(19) United States
(12) Patent Application Publication
(10) Pub. No.: US 2008/0292895 A1
(43) Pub. Date: Nov. 27, 2008

(54) Method of Producing a Gas Barrier Polymer Foil and a Gas Barrier Polymer Foil

(75) Inventors: Maike Benter, Roskilde (DE); Bahram Eshtehardi, Ishoj (DK); Kjeld Schaumburg, Herlev (DK); Henry Kierkegaard, Skodsborg (DK)

Correspondence Address: BUCHANAN, INGERSOLL & ROONEY PC, POST OFFICE BOX 1404, ALEXANDRIA, VA, 22313-1404, US

(73) Assignee: NANON A/S, Brondby (DE)

(21) Appl. No.: 12/095,382

(22) PCT Filed: Nov. 29, 2006
(86) PCT No.: PCT/DK2006/050072

§ 371 Date: May 29, 2008

(30) Foreign Application Priority Data
Nov. 29, 2005 (DK) PA 2005 01678

(51) Int. Cl. B32B 15/04; C23C 16/56; B32B 37/02; C23C 16/02

(52) U.S. Cl. 428/472; 428/469; 428/472.2; 428/472.3; 156/60; 427/579; 427/539

(57) ABSTRACT

The invention relates to polymer foil comprising at least one polymer layer coated with a barrier glass coating of an oxide composition, wherein said oxide composition comprises the element Si in the form of an oxide network, the oxide composition preferably comprises Si and at least one other element X in an oxide network. The oxide network may preferably be applied using plasma. The foil may be a multi-layered foil comprising a plurality of layers, at least one of the layers being a barrier glass coating. The foil has good barrier properties.

### TECHNICAL FIELD

The present invention relates to a polymer foil and a method of producing such a polymer foil.

### BACKGROUND ART

Polymer foils are today used for countless applications such as foils for various packaging purposes. For some applications e.g. packaging of food, foils for ostomy bags and similar, the permeability properties of the polymer foil are very important.

Often such foils are provided by laminating two or more layers with different properties. However, in order to reduce gas permeability several prior art publications suggest application of coatings to the foil.

EP 1 464 481 A1 discloses a foil e.g. of polyethylene terephthalate with a thin barrier deposition layer of metallized aluminium on one side of the foil and another polymer layer adhered onto the other side of the foil. Such metallized foils are often expensive to prepare, and furthermore they are relatively stiff and of course they are non-transparent.

Several prior art publications disclose foils comprising a polymer layer with a glass like coating. U.S. Pat. No. 5,462,779 discloses a polymer film with a barrier coating of SiO₂ and Al₂O₃. U.S. Pat. No. 5,084,3359 discloses a polymeric film substrate and a glassy coating of silicon dioxide heavily doped with at least one metal selected from the group consisting of antimony, aluminium, chromium, cobalt, copper, indium, iron, lead, manganese, tin, titanium, tungsten, zinc, and zirconium. US 2003/0044552 discloses a gas barrier film comprising a polymer substrate with a vacuum deposited glass like film provided by a silicon monomer

The above disclosed foils with glass like coatings have shown to have a relatively high barrier towards gasses such as O₂, CO₂, H₂S, H₂, NH₃ and H₂O (steam). However, the glass-like layer makes the foil relative stiff and likely to form cracks which may deteriorate both its barrier effect and its appearance. The objective of the present invention is thus to provide a foil with relatively high barrier properties against gasses, and which simultaneously is very flexible and has no significant tendency to form cracks due to folding and/or manipulation of the foil.

This objective has been fulfilled by the foil as defined in the claims, and furthermore additional objectives have been achieved by embodiments of the invention as will be disclosed in the following description and claims.

### DISCLOSURE OF INVENTION

The foil of the invention comprises at least one polymer layer and in the following is thus called a polymer foil. At least one polymer layer of the polymer is coated with a barrier glass coating of an oxide composition comprising the element Si in the form of an oxide network.

The term ‘a coating’ is used to denote a layer of a material which is in direct contact with the surface onto which it is applied (coated).

To apply a coating onto a layer thus means to apply a coating directly onto such layer, e.g. in the form of a deposition of material or in form of lamination of a material.

To laminate two or more layers means to apply the pre-produced layers onto each other with or without intermediate layers.

Thus, according to the invention it has surprisingly been found that an oxide composition comprising the element Si in the form of an oxide network provided as a coating onto the polymer layer provides a barrier glass layer of the polymer foil with high gas barrier properties which simultaneously is both very flexible and crack and scratch resistant. The polymer foil of the invention with high barrier properties can thus be handled and folded as desired in use without any significant risk of damaging the barrier properties provided by the barrier glass layer.

It has been found that the element Si should be in an oxidized form and should be in the form of an oxide network. Si provides the barrier glass layer with a very high resistance towards cracks and scratches.

In a preferred embodiment the oxide composition preferably comprises Si and at least one other element X in an oxide network. The at least one other element X may preferably be selected from the group consisting of P, Al and Ti. These other elements, preferably in the form of P, Al and/or Ti provide the barrier glass layer with its desired flexibility and reduce the risk of cracking.

In the following description ‘X’ should be taken to mean at least one of the elements P, Al and Ti.

An oxide network means that the coating should be in an amorphous structure where the Si atoms and optionally other (X atoms) share some of the O atoms to form a network. The barrier glass coating layer is preferably an inorganic layer.

Oxide networks and the formation thereof in general are described in the handbook, Inorganic Polymers, by H. H. Ray, Academic Press, 1978, pages 54-90.

In order to balance the flexibility and the crack/scratch resistance it is desired that the oxide network comprises X element and the Si:X atom ratio amount in the oxide composition is between 10:1 and 1:4. If the amount of Si relative to the amount of X becomes too large, the barrier glass layer may become brittle and there may be a risk of crack formation in the barrier glass coating. If the amount of X relative to the amount of Si becomes too large, the barrier glass coating may become unstable in particular in moisture or liquid environments due to high dissolvability. In one embodiment it is desired that the Si:X atom ratio amount in the oxide composition is between 5:1 and 1:3, such as 3:1 and 1:3, such as 2:1 and 1:2.

In order to provide the glass barrier layer with a desired high flexibility it has been found that the X element preferably should be present in the oxide composition in an amount of between 5.0-30% by atom of the composition, such as between 10.0 and 25.0% by atom, such as between 15.0 and 20.0% by atom of the composition.

In the embodiment where the barrier layer is in the form of an oxide network comprising the X and Si atoms, the barrier layer has shown to be relatively strong compared to its thickness. The barrier layer may though be relatively thin compared with known barrier layers with similar barrier quality and simultaneously be very strong and resistant to damage due to ordinary manipulation of the foil in use.

In one embodiment wherein the oxide network comprises an X element in the form of P, the glass barrier coating has been found to have an even more increased flexibility.

The oxide composition may in one embodiment comprise X element in the form of one or more of the elements selected from the group consisting of Al and Ti. The Al and Ti atoms may preferably be in the form of oxides in an oxide network. The Al and Ti elements may in this embodiment preferably be present in an amount of up to 20% by atom, such as between 1 and 10% by atoms, such as between 2 and 5% by atoms of the oxide composition.

In one embodiment wherein the oxide composition of the glass barrier layer comprises at least one of the elements Al and Ti, these elements are in total present in said oxide composition in amount of up to 50% by atom of the Si element, such as up to 20%, such as up to 10%, such as up to 2% by atom of the Si element.

A polymer foil of the invention comprising Al and/or Ti elements in its glass barrier layer has shown to have very good oxygen barrier properties and has also shown to have a good barrier effect towards other gasses, such as smelling gasses. The Al element may further provide the foil with increased stability and the Ti element may provide the foil with antibacterial properties.

In one embodiment the oxide composition of the glass barrier coating may further comprise one or more of the additional elements selected from the group consisting of the element other than Si of the groups 1, 2, 3, 4, 7, 8, 9, 10, 13 and 14 of the periodic table of the elements, such as e.g. one or more of the elements B, K, Li, Na, Mg, Ca, Fe, Cu, Ag, Zn, Co, Ga, Zr, Y, Ni, Pb, Cd, In, Sn and Mn. These elements may preferably be present in an amount of up to about 20% by atom of the composition, such as up to about 10% by atom, such as between 0.2 and 5%.

This version of the Periodic table referred to herein is based on that recommended by the Commission on the Nomenclature of Inorganic Chemistry and published in IUPAC Nomenclature of Inorganic Chemistry, Recommendations 1990.

In one embodiment the major part by atom of one or more of the elements selected from the group of additional elements consisting of the element other than Si of the groups 1, 2, 3, 4, 7, 8, 9, 10, 13 and 14 of the periodic table of the elements, are present in the form of an oxide network.

As mentioned above, such a glass barrier layer formed by an oxide network is very strong and results in both high scratch resistance and long durability.

The elements Si, X, and one or more of the elements from the group of B, Mg, Ca, Fe, Cu, Ag, Zn, Co, Ga, Zr, Y, Ni, Pb, Cd In, Sn and Mn may preferably form the oxide network by sharing O atoms. The oxide network may preferably comprise one or more elements selected from the group consisting of Na, K and Li in the mesh of the oxide network, e.g. under the influence of ionic forces, such as forming an ion bonding with one of the elements of the oxide network.

The oxide network may preferably comprise alkali earth elements such as cat ions to increase resistance towards hydrolysis, in particular if the polymer foil is adapted to be used in moist environments.

In one embodiment of the polymer foil of the invention the barrier glass coating is a Sl/Si—X oxide network glass coating comprising up to 20%, such as between 0.2 and 5% by weight of other components than oxidized X and Si.

The other components e.g. as described above may be used to modify the properties of the polymer foil, such as resistance towards hydrolysis, resistance towards aggressive chemicals, resistance towards extreme temperatures and other.

In one embodiment of the polymer foil of the invention the barrier glass coating is a P—Si—Al glass coating comprising up to 20%, such as between 0.2 and 5% by atom of other components than oxidized P and Si.

Such polymer foil comprising the element Al has an increased homogeneity and it has shown also to have very good barrier properties, probably due to a closer molecular packing in the material. The Al element may also increase the hardness of the material. In the embodiment of the polymer foil of the invention wherein the barrier glass coating is a P—Si—Al, the Al element may also add to the brittleness of the material and it is thus preferred that the total atom ratio amount of the elements Si and Al (Al+Si) relative to the atom amount of P, i.e. Al+Si:P is less than 10:1, such as between 5:1 and 1:3, such as 3:1 and 1:3, such as 2:1 and 1:2.

In one embodiment of the polymer foil of the invention the barrier glass coating is a P—Si—Ti glass coating comprising up to 20%, such as between 0.2 and 5% by atom of other components than oxidized P and Si.

Such polymer foil comprising the element Ti also has an increased homogeneity and increased barrier properties. Furthermore, the Ti adds antibacterial properties to the foil, which in many applications may be beneficial. Also the Ti element is more simple to apply in a plasma process than Al element, simply because adequate components comprising Ti elements, such as titanium tetrachloride, are relative easy to evaporate. The Ti element may also add to the brittleness of the material and it is thus preferred that the total atom ratio amount of the elements Si and Ti (Ti+Si) relative to the atom amount of P, i.e. Ti+Si:P is less than 10:1, such as between 5:1 and 1:3, such as 3:1 and 1:3, such as 2:1 and 1:2.

In one embodiment of the polymer foil of the invention the barrier glass coating is a P—Si—Ti—Al glass coating comprising up to 20%, such as between 0.2 and 5% by atom of other components than oxidized P and Si.

A polymer foil of the invention comprising both Ti and Al has shown to have very good properties, both with respect to barrier properties and durability. The Al and Ti elements in small amounts, such as up to about 5% by atom, have been found to decrease the solubility of P. The total amount of Si, Al and Ti (Si+Al+Ti) relative to the atom amount of P, i.e. Si+Al+Ti:P should preferably be kept less than 10:1, such as between 5:1 and 1:3 in order to avoid brittleness of the material.

In one embodiment of the polymer foil of the invention the barrier glass coating is a Si glass coating comprising up to 20%, such as between 0.2 and 5% by weight of other components than oxidized Si.

In one embodiment it is desired that the barrier glass coating of the polymer foil comprises as little organic compound as possible, because organic material in the oxide composition of the glass barrier layer may result in incomplete areas in the oxide network, and consequently in a reduced barrier effect. In one embodiment the barrier glass coating comprises less than 6% by weight, such as less than 4% by weight of organic compounds. Preferably the barrier glass layer in its matrix is essentially free of organic compounds. It should be observed that the barrier glass layer may comprise organic compounds in contact with its surface without the organic material interfering with the barrier properties of the glass barrier coating.

In one embodiment the glass barrier coating is transparent, and more preferably the polymer foil is transparent. Such transparent foils are preferred for packing material.

In one embodiment the polymer foil is not transparent and preferably comprises a metal layer or a non-transparent polymer layer e.g. a coloured polymer layer. Such polymer foils may e.g. be useful in ostomy bags and packing material where the packed product should not be visible.

As mentioned above, the barrier glass layer need not be very thick to provide a desired barrier effect. In most situations a thickness of about 5 nm may be sufficient. Thus in general the desired thickness of the glass barrier layer is about 500 nm or less, such as in the interval between 1 and 200 nm, such as between 5 and 100 nm, such as between 10 and 70 nm.

In situation where high security is needed, the thickness of the glass barrier layer may be higher, but in such situations it is most often more efficient to laminate two or more polymer layers which are both/all coated with a glass barrier coating.

In one embodiment the barrier glass coating has an essentially homogeneous composition. In another embodiment the barrier glass coating comprises two or more barrier glass sub-layers with different compositions. The composition of the respective barrier glass sub-layers may preferably be essentially homogeneous. By providing the glass barrier layer with barrier glass sub-layers, the various properties may be provided in various layers to obtain an even more improved glass barrier layer.

In one embodiment the barrier glass coating comprises alternating SiO₂ and Si or Si—X oxide networks barrier glass sub-layers, which barrier glass sub-layers independently of each other optionally comprise up to 20% by mol of the sub-layer composition of the elements selected from the element other than Si of the groups 1, 2, 3, 4, 7, 8, 9, 10, 13 and 14 of the periodic table of the elements, such as B, K, Li, Na, Mg, Ca, Fe, Cu, Ag, Zn, Co, Ga, Zr, Y, Ni, Pb, Cd, In, Sn and Mn. In this embodiment the flexibility and strength may be even more improved, as the X amount in the Si—X oxide network sub-layer may be relatively high, whereby the Si—X oxide network sub-layer provides the foil with even more increased flexibility and mechanical strength. The alternating SiO₂ sub-layer which could be very thin e.g. about 50 nm or less, such as about 25 nm provides the foil with increased barrier properties. A foil with several very thin SiO₂ barrier glass sub-layers may thus have a higher gas barrier than a foil with one SiO₂ layer with a thickness corresponding to the sum of the thickness of the SiO₂ barrier glass sub-layers.

The barrier glass coated polymer layer may in principle be as thick as desired, but in practice it is desired that the polymer layer and the whole polymer foil are relatively thin because of both cost and handleability. Thus in most embodiments it is desired that the barrier glass coated polymer layer has a thickness of up to 2 mm, such as up to 1 mm, such as between 1 and 500 μm, such as at least 15 μm.

In one embodiment the foil has a thickness of up to 5 mm, such as between 2 and 500 μm, such as between 20 and 50 μm.

In one embodiment the surface of the barrier glass layer is essentially free of organic compounds. The layer will thereby be relatively stable and resistant to further oxidation.

In one embodiment at least a part of the surface of the barrier glass layer is connected to organic material. Or in other words, a layer of organic material is applied onto at least a part of the surface of the barrier glass layer.

In one embodiment the organic material may be applied onto at least a part of the surface of the barrier glass layer by being welded, coated e.g. by plasma deposition or lamination, with an organic material. Most preferred the organic material applied onto the surface of the barrier glass layer is a plasma deposited layer.

In one embodiment the organic material applied onto the barrier glass coating may be a polymer coating with a thickness of 500 nm or less, preferably in the interval between 1 and 200 nm, such as between 5 and 100 nm, such as between 10 and 70 nm.

The polymer foil of the invention comprising an organic material layer, e.g. a plasma deposited layer, applied onto the barrier glass coating, is much easier to laminate with additional layers, e.g. polymer layers, and also it is easier to weld such polymer foils, which is an important property in many applications of the foil, such as for use as packing material and for ostomy bags and similar.

The organic material applied onto the barrier glass coating may preferably be selected from the group consisting of amides, esters, alcohols, alkanes, alkenes, alkines, ethers and mixtures thereof, preferably in polymerized form.

In one embodiment the organic material is an organic layer applied by plasma assisted vapour deposition (PVD), the organic layer preferably being obtained by PVD of at least one of the monomers selected from the group consisting of C1-C16 alkanes, C2-C16 alkenes, C2-C16 alkynes, C2-C16 alkynes, C2-C16 alkines, styrene, aromatic monomers of styrene compounds, vinyl compounds, acrylic compounds, amide compounds, amine compounds, ester compounds, aldehyde compounds ketone compounds, alcohol compounds, nitrils (e.g. acrylnitril) and hexene.

In one embodiment the barrier glass coated polymer layer is laminated with one or more laminating layers, such as a laminating polymer layer, preferably at least one of said one or more laminating layers, is applied onto the coated side of the barrier glass coated polymer layer. The barrier glass coating is preferably provided with surface coating of organic material prior to the lamination to thereby provide a stronger bonding in the laminating interface.

The one or more polymer layers of the foil may in one embodiment be of a polymer material selected from the group consisting of silicone (silicone rubber), PE (polyethylene), PET (thermoplastic polyester [polyethylene ter-phthalate]), PC (polycarbonate), PP (polypropylene), PA (polyamide), EVA (ethylene vinyl acetate) or mixtures comprising one or more of these polymers.

In a preferred embodiment the polymer layer coated with a glass barrier layer is silicone. In general silicone has not hitherto been attractive to use in foils where barrier properties are important as silicone provides a relatively low barrier against gasses and migration of materials in general. However, a silicone with a glass barrier coating has shown to provide a very good barrier against gasses. A foil according to the invention wherein the polymer layer coated with a glass barrier layer is silicone is thus very suitable for use in the production of products with a barrier requirement to be used in contact with human and animal skin, such as ostomy bags.

The foil of the invention may comprise other layers such as additional polymer layers and/or fibrous layers e.g. of textile of cellulose fibres, preferably in the form of non woven layers. Such layers do normally not provide any barrier effect against gasses, but it may e.g. provide a soft and/or decorative surface of the polymer foil.

In one embodiment at least one layer, preferably a polymer layer of the foil is impregnated with a non-polymeric component. Such non-polymeric component may preferably be selected from the group consisting of activated carbon black, metals, metal complexes, organo metal compounds of at least one of the elements Ag, Fe, Cu, Co, Ni, and mixtures thereof. These non-polymeric components may provide the polymer foil with additionally improved barrier properties.

In one embodiment the polymer foil comprises two or more polymer layers. Preferably one or more layers of the foil are provided by plasma assisted vapour deposition (PVD). The PVD provided layer may be obtained by PVD of at least one of the monomers selected from the group consisting of C1-C16 alkanes, C2-C16 alkenes, C2-C16 alkynes, C2-C16 alkynes, C2-C16 alkines, styrene, aromatic monomers of styrene compounds, vinyl compounds, acrylic compounds, amide compounds, amine compounds, ester compounds, aldehyde compounds ketone compounds, alcohol compounds, nitrils (e.g. acrylnitril) and hexene, preferably the barrier glass layer being coated onto said PVD provided layer.

The invention also relates to a method of producing the polymer foil of the invention. The method of the invention comprises the steps of providing a polymer layer substrate and coating said polymer layer substrate with a barrier glass coating comprising an oxide composition with elements Si in the form of an oxide network, the barrier glass coating preferably comprising an oxide composition as described above.

In principle the oxide composition can be applied using several methods e.g. by applying the coating as a sol-gel or by plasma deposition.

Information about sol-gel methods can be found in “Preparation of P₂O₅—SiO₂ glasses with proton conductivity of ˜100 mS/cm at room temperature”, by M. Nogami et al. Journal of the Electrochemical Society, 151 (12) A2095-A2099 (2004). This method may be used by applying the hydrolyzed solution of the components in a thin layer onto the polymer layer substrate, forming and solidifying the gels as described in the article. When using the sol-gel method the polymer layer substrate should be a high temperature stable polymer layer substrate, such as a substrate of PA, PET or silicone rubber, capable of withstanding the sol-gel method temperatures which are normally from about 400° C. and higher.

In a preferred method the oxide composition is applied using plasma deposition. Thereby a very homogenous layer can be obtained. The method in this preferred embodiment thus preferably comprises the steps of placing the polymer layer substrate in a reaction chamber and subjecting the substrate to a plasma deposition treatment for deposition of the barrier glass coating.

By using plasma deposition for applying the oxide composition with the elements Si and P the coating can be applied in a very simple and economical manner. Simultaneously the applied oxide coating can be provided with a desired homogeneity along the surface. As will be described below, it may be desired to apply several oxide layers, which respective layers preferably may be essentially homogenous as it is possible to obtain using plasma deposition.

Also it should be mentioned that it has surprisingly been found that the oxide layer comprising the elements Si in an oxide network may be relatively thin as described above, which is beneficial because of both the reduced use of material and thereby reduced cost, but also because of the simpler handling of thin foils than thick foils. By using plasma deposition the oxide layer with the elements Si in an oxide network can be provided as thin as desired.

In principle any plasma deposition methods may be used. The plasma is generated by subjecting gas to an electric field generated by an electrode system comprising two or more electrodes connected to a power source. The power source may in principle be any type of power source e.g. preferably selected from the group consisting of an alternating current (AC), a direct current (DC), low frequency (LF), audio frequency (AF), radio frequency (RF) and microwave power source e.g. as described in EP 831 679 or WO 00/44207 which are hereby incorporated by reference.

The skilled person will be able to find operable conditions for the plasma deposition.

In a preferred embodiment the pressure in the plasma deposition treatment step is 50 Pa or below, below 35 Pa, such as between 1 and 30 Pa, such as between 5 and 15 Pa, such as between 5 and 10 Pa, such as between 1 and 5 Pa., such as between 7 and 12 Pa.

The plasma deposition treatment comprises plasma treatment in the presence of a monomer gas, which monomer gas is broken down to a desired level in the plasma and reacted to form a desired deposited layer. In one embodiment the monomer gas comprises one or more of the compositions selected from the group consisting of organosilicon compositions, organophosphorous, organoborate, and/or other organo metallic compounds such as Li, Na, Al and Ti; inorganic components such as inorganic hydrides, e.g. hydrides of one or more of the elements P, B, Si, K, Li, Na, Mg, Ca, Ti, Fe, Cu, Ag, Zn, Al, Co, Ga, Zr, Y, Ni, Pb, Cd, In, Sn and Mn; and one or more of the basic elements selected from the group consisting of the elements of the groups 1, 2, 3, 4, 7, 8, 9, 10, 13, 14 and 15 of the periodic table of the elements, such as the elements P, B, Si, K, Li, Na, K, Mg, Ca, Ti, Fe, Cu, Ag, Zn, Al, Co, Ga, Zr, Y, Ni, Pb, Cd, In, Sn and Mn.

In a preferred embodiment the monomer gas comprises at least one organosilicon such as hexamethyldisiloxane, methoxytrimethylsilane, tetramethoxysilane, hexamethylcyclotrisiloxane, methyltriethoxysilane, or phenyltriethoxysilane.

In a preferred embodiment the monomer gas comprises at least one organophosphorous such as trimethylphosphite, trimethylphosphate, triethylphosphate, Di-1-propylphosphite, Diphenylphosphine, Dimethylphenylphosphine, Dimethylmethylphosphonate, diethylphsphite, tri-n-propylphosphine.

In a preferred embodiment the monomer gas comprises at least one organoborate and/or halogenated boron compounds such as trimethylborate, triethylborate, tri-n-propylborate, tris(trimethylsilyl)borate, triethoxyboroxine, BX₃ and B₂X₄, wherein X means halogen selected from the group consisting of F, Cl and Br.

In a preferred embodiment the monomer gas comprises at least one organo aluminium compound and/or one halogenated aluminium compound such as at least one of the compounds trimethylaluminium, triethylaluminium, tris(dimethylamido)aluminium, aluminium t-butoxide, aluminium isopropoxide, aluminium acetylacetine and aluminiumtrichloride.

In a preferred embodiment the monomer gas comprises one or more of the hydrides, AlH₃, PH₃, P₂H₄, P₃H₅, BH₃, B₂H₆, B₄H₁₀, B₅H₉, and SiH₄, Si₂H₆, Si₃H₈.

The above mentioned components for the monomer gas may be combined in various amounts to obtain the desired finished composition of the glass barrier layer as described above.

The respective amounts of the components in the monomer gas may in one embodiment be varied during the plasma deposition step, whereby a variation of the composition of the glass barrier coating in its thickness direction will be formed.

Thus in one embodiment the amount of X containing monomer is relatively high in a first step of the plasma deposition and the amount of Si containing monomer is relatively high in a first step of the plasma deposition, said first deposition step being followed by a second deposition step wherein the amount of X containing monomer is lower than in the first step, the plasma deposition and the amount of Si containing monomer being higher than in the first step of the plasma deposition. The change of the respective amounts of monomers may be varied step-wise or in a continuous manner.

In one embodiment the monomer gas is fed into the reaction chamber in an amount of between 0.1 and 100 ml/min as determined at 25° C. and 1 atm.

The monomer gas may preferably be fed into the reaction chamber together with a support gas. The support gas should be essentially inactive for the reaction, but as it is known from the prior art support gas may be captured in the deposited material without having chemically reacted with said deposited material.

In one embodiment using plasma deposition the monomer gas is fed into the reaction chamber using a support gas selected from the group consisting of inert gases and oxidizing gasses. The support gas may preferably be selected from the group consisting of N₂O, Ar, O₂ and mixtures thereof.

The support gas may further be used to regulate the pressure within the reactor to a desired level.

The deposition step may preferably be performed for at least 1 minute. The length of the deposition step depends largely on the desired thickness of the applied layer. In most situations a deposition treatment time of up to 120 minutes is sufficient. In one embodiment the deposition treatment time is at least 5 minutes, such as between 5 and 120 minutes, such as between 10 and 60 minutes.

In one embodiment the plasma deposition further comprises a step of pre-treating the surface of the polymer layer substrate. The pre-treating step may preferably be performed prior to the deposition step.

The pre-treating step need not be performed immediately prior to the plasma deposition step, but in general it is preferred that it is performed within 24 hours, more preferably within 5 hours, more preferably within 2 hours before the plasma deposition. Often it is most simple to perform the pre-treatment step immediately prior to the plasma deposition step.

The pre-treating step may preferably be performed in order to clean the surface of the polymer layer substrate prior to the deposition step.

The pre-treating step may preferably comprise the step of subjecting the polymer layer substrate surface to an oxidizing gas. The oxidizing gas in the pre-treatment step preferably comprises one or more oxidizing components selected from the group consisting of O₂, N₂O and mixtures thereof optionally including H₂, the oxidizing gas preferably comprises one or more oxidizing components in combination with one or more inert gasses selected from the group consisting of argon helium neon and krypton.

In one embodiment of the method of the invention the oxidizing gas used in a pre-treating step comprises a mixture of O₂ and argon.

In one embodiment of the method of the invention the oxidizing gas used in a pre-treating step comprises a mixture of argon and H₂, or H₂ and O₂, or argon and O₂ or argon and N₂O.

The pre-treatment step may preferably be performed in a plasma.

The pre-treatment step may preferably be performed in a plasma, e.g. generated by any of the power sources as disclosed above. The pressure in the pre-treatment plasma may preferably be 50 Pa or below, such as below 35 Pa, such as between 1 and 30 Pa, such as between 10 and 15 Pa, such as between 5 and 10 Pa, such as between 1 and 5 Pa.

The treatment time for the pre-treatment step is not so important and may e.g. be between 5 and 500 seconds. A pre-treatment beyond 500 will in most circumstances not have any further effect than a 500 second treatment time pre-treatment.

In one embodiment the method of the invention using plasma deposition further comprises a post-treatment step of post-treating the coated surface of the polymer layer substrate. The post-treatment step is performed after termination of the deposition step.

The post-treatment step may preferably include treatment with an oxidizing component in a plasma. The oxidizing component may preferably be oxygen.

The post-treatment step may e.g. be performed in a plasma under similar pressure conditions as the pre-treating step described above.

In general the post-treatment step may be performed for e.g. 1 minute to weeks, but in practice the post-treatment may preferably be performed for at least 15 minutes, preferably between 0.5 and 5 minutes, such as between 1 and 3 minutes.

An example of a preferred embodiment of the method of the invention is as follows:
a. placing the polymer layer substrate in a reaction chamber
b. pre-treating the surface of the polymer layer substrate by subjecting it to an oxidizing gas, and
c. subjecting the polymer layer substrate to a plasma deposition treatment for deposition of a barrier glass coating.

A further example of a preferred embodiment of the method of the invention is as follows:
a. placing the polymer layer substrate in a reaction chamber;
b. pre-treating the surface with O₂, N₂O, inert gas or a mixture of argon, O₂, N₂O, preferably argon, O₂, or N₂O, argon, and
c. treating the polymer layer substrate in a plasma deposition step with at least one of the mixtures:
a mixture containing an organophosphorous and organoborate compound,
a mixture containing an organophosphorous, organoborate and silanes compound, and
a mixture containing an organophosphorous, organoborate, silanes, and other organo metallic compounds such as organo metallic compounds comprising Li, Na, Al and Ti.

As described above the polymer foil of the invention may comprise other layers e.g. coated layers such as layers applied by plasma deposition, spraying, painting laminating and other. These layers may be added to the glass barrier coated polymer layer using any conventional method.

In one embodiment the method of the invention comprises the step of providing at least one laminating layer, such as a polymer layer, and laminating said at least one laminating layer with said coated polymer layer substrate. Preferably at least one of said laminating layer is applied onto the barrier glass coated side of said polymer layer substrate, optionally with an organic coating in-between to improve adherence.

In one embodiment the method of the invention comprises the step of applying an organic coating onto the barrier glass coating. This organic coating may provide a layer which as described above is easier to adhere, laminate and/or weld onto.

The organic coating may e.g. be a polymer coating with a thickness of 500 nm or less, such as in the interval between 1 and 200 nm, such as between 5 and 100 nm, such as between 10 and 70 nm. Also here it is often desired to keep the thickness as small as possible in order to minimize the total thickness of the polymer foil of the invention.

The organic coating may preferably be applied using plasma deposition. In one embodiment the plasma deposition for applying the organic coating comprises using a monomer selected from the group consisting of alkanes, alkenes, alkines, vinyl compounds, acrylic compounds, amide compounds, amine compounds, ester compounds, aldehyde compounds ketone compounds, alcohol compounds and a mixture thereof the monomer preferably comprises 2-12 carbon atoms, such as C2-C12 hydrocarbons.

In one embodiment the organic coating is applied using plasma deposition comprising using a monomer selected from the group consisting of C1-C16 alkanes, C2-C16 alkenes, C2-C16 alkynes, C2-C16 alkynes, C2-C16 alkines, styrene, aromatic monomers of styrene compounds, vinyl compounds, acrylic compounds, amide compounds, amine compounds, ester compounds, aldehyde compounds ketone compounds, alcohol compounds, nitrils (e.g. acrylnitril), hexene and a mixture thereof.

In one embodiment the method of the invention further comprises the step of providing an impregnated layer. This impregnated layer may preferably be impregnated with a non-polymer component, such as a non-polymer component preferably selected from the group consisting of metals, metal complexes and organo metal compounds of at least one of the elements of the groups 4, 8, 9, 10, 11 and 13 of the periodic table of the elements, such as Ag, Cu, Co and Fe. The impregnated layer may for instance be an impregnated polymer layer or an impregnated fiber layer, such as a non woven layer of cellulose and or textile.

In one embodiment the impregnated layer is an impregnated polymer layer. In this embodiment the impregnated polymer layer may e.g. be the polymer layer substrate.

In case said impregnated layer is not the polymer layer substrate this impregnated layer be laminated with the polymer layer substrate.

The impregnation may have various purposes, such as to provide a desired colour, to provide a desired smell or to incorporate a smell reducing component (e.g. active carbon particles), to incorporate a pesticide, such as a herbicide, a fungicide, a weedicide an insecticide, a nematicide, a germicide and/or a bactericide.

The impregnation may furthermore be provided to impregnate a polymer layer with a gas barrier element to increase the barrier properties of said polymer layer. Such a gas barrier element may e.g. be a compound which reacts as a chemical barrier (e.g. a silver complex which reacts with a sulphur-gas to silver sulphide and immobilizes the sulphur gas) or a physical barrier (e.g. particles which fill the pores of a polymer foil whereby gas molecules no longer will be able to migrate through the foil).

The impregnated layer, preferably a polymer layer may preferably be obtained by providing a layer for impregnation and subjecting said layer to an impregnating step, comprising treatment with a non polymer component in the presence of CO₂ in liquid or supercritical state.

Condition for the impregnation can e.g. be as described in the deposition step of incorporating into silicone material as described in WO 03/68846.

In one embodiment the layer for impregnation in the impregnating step is subjected to a pressure of at least 10 bars, such as between 20 and 300 bars, such as between 40 and 80 bars or such as between 80 and 120 bars.

The temperature in the impregnating step may preferably be between 10 and 120° C., such as between 25 and 100° C., such as between 40 and 80° C.

The invention also relates to a polymer barrier foil comprising an impregnated polymer layer, wherein the impregnation is as described above. The polymer layer may e.g. be any of the above disclosed polymer materials useful for the glass barrier coated polymer described above.

### EXAMPLES

### Example 1

### Preparation of a Polymer Foil with a Multi Layer Barrier Glass Coating

3 different coating treatments are carried out test A, test B and test C. For each test two polymer samples are treated, a PET and a PE foil both with the dimensions 0.1 mm×50 mm×40 mm.

The monomers used are as follows:

### Mono1=Hexamethyldisiloxane (HMDSO)

### Mono2=Trimethylphosphite (TMP)

### Mono3=Hexene

Mono4=tetramethoxysilane

### Mono5=Al (III) or Ti (IV)

The plasma chamber to be used has a volume of 12.1 L (3 phase AC plasma, with a max current and voltage at 200 mA and 650V on 50 Hz). The below tables 1A, 1B and 1C show the parameters and conditions.

Pre-treatment: The pre-treatment step is made to clean and activate the surface of the foils. The pre-treatment is performed in the plasma under the conditions as shown in the tables 1A, 1B and 1C.

Treatment: After pre-treatment (after 30 seconds of pre-treatment as indicated below) the treatment is initiated with step 2. The treatment comprises 7 steps with varying conditions as indicated in the tables 1A, 1B and 1C. The treatment steps are performed consecutively after each other. The time indicates the treatment time of each step. The adjustment time from one step (the ceasing step) to the next step (the beginning step) is a few seconds which are included in the treatment time of the beginning step.

End process and Purge: When the total treatment time is over, the power is turned off and all the valves to the monomers are turned of.

Results and discussion: The barrier properties of the foils are measured by diffusion of O₂. The barrier properties are improved by a factor of more than 20 compared to an untreated reference foil.

The layer of monomer 3 (hexane) made a lamination possible.

TABLE A

| | O2 | H2 | Ar | power | pressure | mono1 | mono2 | Mono3 | Time |
|---|---|---|---|---|---|---|---|---|---|
| | ml/min | ml/min | ml/min | W | Pa | ml/min | ml/min | ml/min | min |
| Step 1 - pre treating | 0 | 2 | 6 | 150 | 6 | 0 | 0 | 0 | 0.5 |
| Step 2 - Treating | 25 | 0 | 0 | 250 | 10 | 2.5 | 0 | 0 | 1 |
| Step 3 - Treating | 25 | 0 | 0 | 250 | 10 | 2.5 | 2.5 | 0 | 2 |
| Step 4 - Treating | 25 | 0 | 0 | 250 | 10 | 0 | 2.5 | 0 | 1 |
| Step 5 - Treating | 25 | 0 | 0 | 250 | 10 | 2.5 | 2.5 | 0 | 2 |
| Step 6 - Treating | 25 | 0 | 0 | 250 | 10 | 2.5 | 0 | 0 | 1 |
| Step 7 - Treating | 25 | 0 | 0 | 250 | 10 | 2.5 | 2.5 | 0 | 2 |
| Step 8 - Treating | 0 | 0 | 8 | 100 | 8 | 0 | 0 | 6 | 4 |

TABLE B

| | O2 | H2 | Ar | power | pressure | mono4 | mono2 | Mono3 | Time |
|---|---|---|---|---|---|---|---|---|---|
| | ml/min | ml/min | ml/min | W | Pa | ml/min | ml/min | ml/min | min |
| Step 1 - pre treating | 0 | 2 | 6 | 150 | 6 | 0 | 0 | 0 | 0.5 |
| Step 2 - Treating | 25 | 0 | 0 | 250 | 10 | 2.5 | 0 | 0 | 1 |
| Step 3 - Treating | 25 | 0 | 0 | 250 | 10 | 2.5 | 2.5 | 0 | 2 |
| Step 4 - Treating | 25 | 0 | 0 | 250 | 10 | 0 | 2.5 | 0 | 1 |
| Step 5 - Treating | 25 | 0 | 0 | 250 | 10 | 2.5 | 2.5 | 0 | 2 |
| Step 6 - Treating | 25 | 0 | 0 | 250 | 10 | 2.5 | 0 | 0 | 1 |
| Step 7 - Treating | 25 | 0 | 0 | 250 | 10 | 2.5 | 2.5 | 0 | 2 |
| Step 8 - Treating | 0 | 0 | 8 | 100 | 8 | 0 | 0 | 6 | 4 |

Test C

| | O2 | H2 | Ar | power | pressure | mono4 | mono2 | Mono3 | Mono5 | Time |
|---|---|---|---|---|---|---|---|---|---|---|
| | ml/min | ml/min | ml/min | W | Pa | ml/min | ml/min | ml/min | ml/min | min |
| Step 1 - pre treating | 0 | 2 | 6 | 150 | 6 | 0 | 0 | 0 | 0 | 0.5 |
| Step 2 - Treating | 30 | 0 | 0 | 250 | 10 | 2.5 | 0 | 0 | 2 | 1 |
| Step 3 - Treating | 30 | 0 | 0 | 250 | 10 | 0 | 2.5 | 0 | 2 | 2 |
| Step 5 - Treating | 30 | 0 | 0 | 250 | 10 | 2.5 | 0 | 0 | 2 | 1 |
| Step 6 - Treating | 30 | 0 | 0 | 250 | 10 | 0 | 2.5 | 0 | 2 | 2 |
| Step 7 - Treating | 30 | 0 | 0 | 250 | 10 | 2.5 | 0 | 0 | 2 | 1 |
| Step 8 - Treating | 30 | 0 | 0 | 250 | 10 | 0 | 2.5 | 0 | 2 | 2 |
| Step 9 - Treating | 0 | 0 | 8 | 100 | 8 | 0 | 0 | 6 | 0 | 4 |

### Example 2

### Preparation of a Polymer Foil with Impregnation

4 sample substrates of foils with a thickness of 0.1 mm are tested

The substrate is put together with the compound that is supposed to be the impregnating compound, into a high pressure chamber that is provided with a magnetic stirrer in the bottom. The chamber is heated up to 70° C. and pressurized by feeding with CO₂ to a pressure of 300 bars. After the impregnation time the pressure is decreased slowly to atmospheric pressure while the temperature is decreased to room temperature. The samples are weighed after some hours (all CO₂ has been evaporated) to calculate the increase of mass.

In table 2 the following is listed, the substrate, the impregnating compound, the relative amount of impregnating compound incorporated, condition during the impregnation, the co-solvent if any, the condition during the impregnation (temperature, pressure, time) and the increase in mass.

TABLE 2

| | | M_{Ag-compound}/ | | | | | Increase |
|---|---|---|---|---|---|---|---|
| | | M_{substrate} | | | | | of mass |
| Substrate | Impregnating compound | [%] | Co-solvent | T [° C.] | P [bar] | t_{imp.} [h] | [%] |
| PET foil | 1,5- | 5 | — | 70 | 300 | 3 | 2.1 |
| | Cyclooctadiene(hexafluoro | | | | | | |
| | acetylacetonato)silver(1) | | | | | | |
| PET foil | 1,5- | 44 | — | 70 | 300 | 3 | 2.3 |
| | Cyclooctadiene(hexafluoro | | | | | | |
| | acetylacetonato)silver(1) | | | | | | |
| PDMS | 1,5- | 8.75 | — | 70 | 300 | 20 | 3.1 |
| | Cyclooctadiene(hexafluoro | | | | | | |
| | acetylacetonato)silver(1) | | | | | | |
| PDMS | Silver(I)lactate | 10 | EtOH, 10% | 70 | 300 | 20 | 0.3 |

The foils are tested by passing a small amount of hydrogen sulphide (evaporates from ammonia sulphide) through the foil. The colour changes from brown to black (because silver sulphide precipitates in the foil).

### Example 3

### Preparation of a Polymer Foil with a Barrier Glass Coating and an Organic Top Coating

2 layers are applied in a number of treatment steps as shown in table 3. The first applied layer is a barrier glass coating, and the second applied layer in an organic coating. For each test two polymer samples are treated, the samples are from PELD foil with the dimension 35 μm×400 mm×240 mm.

The plasma chamber is cylindrical with a volume of approx. 18 L and a power supplier with a max voltage and effect at 10 kV and 1000 W on 40 KHz).

The monomers and gasses used are as follows:

The monomers and gases used are as follows:

Mono1=tetramethoxysilane (TMOS)

### Mono2=Acrylnitril (AN)

### Gasses: Oxygen and Argon

Pre-treatment: The pre-treatment step is made to clean and activate the surface of the foils.

Treatment: After pre-treatment (20 seconds) the treatment is initiated with step 2. The treatment comprises 7 steps with varying conditions as indicated in the table. The treatment steps are performed consecutively after each other. The time indicates the treatment time of each step. The adjustment time from one step (the ceasing step) to the next step (the beginning step) is a few seconds which are included in the treatment time of the beginning step.

End process and Purge: When the total treatment time is over, the power is turned off and all the valves to the monomers are turned off.

Results and discussion: The barrier properties of the foils are measured by diffusion of O₂. The barrier properties are improved by a percentage of more than 94 compared with an untreated reference foil.

The layer of monomer 2 in steps 8 and 9 (acrylnitril) improves the adherence to an amide which may optionally be applied in a subsequent lamination. It is also observed that the layer of monomer 2 improves the barrier effect.

TABLE 3

| | O2 | Ar | power | pressure | mono1 | mono2 | Time |
|---|---|---|---|---|---|---|---|
| | ml/min | ml/min | W | Pa | ml/min | ml/min | min |
| Step 1 - pre treating | 0 | 10 | 80 | 6.3 | 0 | 0 | 0.3 |
| Step 2 - Treating | 0 | 10 | 80 | 11.7 | 12 | 0 | 1.5 |
| Step 3 - Treating | 10 | 10 | 80 | 12.9 | 12 | 0 | 1.5 |
| Step 4 - Treating | 15 | 5 | 120 | 13.5 | 12 | 0 | 1 |
| Step 5 - Treating | 20 | 1 | 150 | 14.2 | 12 | 0 | 1 |
| Step 6 - Treating | 25 | 1 | 200 | 15.3 | 12 | 0 | 1 |
| Step 7 - Treating | 25 | 0 | 250 | 15.4 | 12 | 0 | 3 |
| Step 8 - Treating | 5 | 10 | 60 | 8 | 0 | 10 | 0.2 |
| Step 9 - Treating | 0 | 10 | 40 | 7 | 0 | 10 | 4 |

1-65. (canceled)

66. A polymer foil comprising at least one polymer layer coated with a barrier glass coating of an oxide composition, wherein said oxide composition comprises the element Si in the form of an oxide network.

67. The polymer foil as claimed in claim 66, wherein the oxide composition comprises Si and at least one other element X in an oxide network.

68. The polymer foil as claimed in claim 66, wherein said at least one other element X is selected from P, Al and Ti.

69. The polymer foil as claimed in claim 67, wherein said at least one other element X is present in an atom amount of at least about the amount of Si element.

70. The polymer foil as claimed in claim 66, wherein said oxide composition comprises one or more of the elements selected from Al and Ti in said oxide network in an amount of up to about 20% by atom.

71. The polymer foil as claimed in claim 66, wherein said oxide composition further comprises one or more additional elements selected from the element other than Si of the groups 1, 2, 3, 4, 7, 8, 9, 10, 13 and 14 of the periodic table of the elements.

72. The polymer foil as claimed in claim 66, wherein said barrier glass coating is a P—Si—Ti—Al glass coating comprising up to about 20% by weight of other components than oxidized P and Si.

73. The polymer foil as claimed in claim 66, wherein said barrier glass coating is a Si glass coating comprising up to about 20% by weight of other components than oxidized Si.

74. The polymer foil as claimed in claim 66, wherein said barrier glass coating comprises less than about 6% by weight of organic compounds.

75. The polymer foil as claimed in claim 66, wherein said barrier glass coating is transparent.

76. The polymer foil as claimed in claim 66, wherein the barrier glass coating has a thickness of about 500 nm or less.

77. The polymer foil as claimed in claim 66, wherein the barrier glass coating comprises two or more barrier glass sub-layers with different compositions.

78. The polymer foil as claimed in claim 77, wherein the barrier glass coating comprises alternating SiO₂ and Si-oxide network barrier glass sub-layers, which barrier glass sub-layers independently of each other comprise at least one other element X selected from P, Al and Ti.

79. The polymer foil as claimed in claim 66, wherein the barrier glass coated polymer layer has a thickness of up to about 2 mm.

80. The polymer foil as claimed in claim 66, wherein the polymer foil is a multilayered foil comprising at least one polymer layer and at least one barrier glass layer coated onto said polymer layer, at least a part of the surface of the barrier glass layer being connected to organic material.

81. The polymer foil as claimed in claim 80, wherein the barrier glass coated polymer layer comprises at least one coating of organic material applied onto the barrier glass coating, said organic material coating being a polymer coating with a thickness of about 500 nm or less.

82. The polymer foil as claimed in claim 81, wherein the organic material is an organic layer applied by plasma assisted vapour deposition (PVD).

83. The polymer foil as claimed in claim 66, wherein the at least one barrier glass coated polymer layer is laminated with one or more laminating layers.

84. The polymer foil as claimed in claim 66, wherein one or more polymer layers of the foil are of a polymer material selected from silicone (silicone rubber), PE (polyethylene), PET (thermoplastic polyester [polyethylene ter-phthalate]), PC (polycarbonate), PP (polypropylene), PA (polyamide), EVA (ethylene vinyl acetate) and mixtures comprising one or more of these polymers.

85. A method of producing a polymer foil as claimed in claim 66, the method comprising
providing a polymer layer substrate, and
coating said polymer layer substrate with a barrier glass coating comprising an oxide composition with the elements Si in the form of an oxide network.

86. The method as claimed in claim 85, wherein said barrier glass coating is applied using plasma deposition, the method comprising placing the polymer layer substrate in a reaction chamber and subjecting the substrate to a plasma deposition treatment for deposition of the barrier glass coating.

87. The method as claimed in claim 86, wherein the pressure during at least a part of the plasma deposition treatment is about 50 Pa or below.

88. The method as claimed in claim 86, wherein the plasma deposition treatment comprises plasma treatment in the presence of a monomer gas, the monomer gas comprising one or more of the compositions selected from organosilicon compositions, organophosphorous, organoborate, other organo metallic compounds; inorganic components; and one or more of the basic elements selected from the groups 1, 2, 3, 4, 7, 8, 9, 10, 13, 14 and 15 of the periodic table of the elements.

89. The method as claimed in claim 86, further comprises pre-treating the surface of the polymer layer substrate, said pre-treating being performed prior to the deposition treatment.

90. The method as claimed in claim 89, wherein the pre-treatment is performed in a plasma.

91. The method as claimed in claim 86, further comprising post-treating the surface of the polymer layer substrate, said post-treatment being performed after termination of the deposition treatment.

92. The method as claimed in claim 91, wherein the post-treatment includes treatment with an oxidizing component in a plasma, the oxidizing component being oxygen.

93. The method as claimed in claim 86, wherein the method comprising:
placing the polymer layer substrate in a reaction chamber,
pre-treating the surface of the polymer layer substrate by subjecting it to an oxidizing gas, and
subjecting the polymer layer substrate to a plasma deposition treatment for deposition of a barrier glass coating.

94. The method as claimed in claim 93, wherein the method comprising:
placing the polymer layer substrate in a reaction chamber;
pre-treating the surface with O₂, N₂O, inert gas or a mixture of argon/H₂, or H₂/O₂, or argon/O₂ or argon/N₂O; and
treating the polymer layer substrate by plasma deposition with at least one of the mixtures:
a mixture containing an organophosphorous and organoborate compound,
a mixture containing an organophosphorous, organoborate and a silane compound, and
a mixture containing an organophosphorous, organoborate, a silane, and other organo metallic compounds.

95. The method as claimed in claim 86, comprising applying an organic coating onto the barrier glass coating, said organic coating being a polymer coating with a thickness of less than about 2000 nm.

96. The method as claimed in claim 95, wherein the organic coating is applied using plasma deposition, the plasma deposition comprising using a monomer selected from C1-C16 alkanes, C2-C16 alkenes, C2-C16 alkynes, C2-C16 alkines, styrene, aromatic monomers of styrene compounds, vinyl compounds, acrylic compounds, amide compounds, amine compounds, ester compounds, aldehyde compounds, ketone compounds, alcohol compounds, nitrils, hexene and a mixture thereof.
